(19) United States
(12) Patent Application Publication
(10) Pub. No.: US 2023/0054960 A1
(43) Pub. Date: Feb. 23, 2023

(54) SIDE-FILLING RESIN COMPOSITION, SEMICONDUCTOR DEVICE, AND METHOD FOR REMOVING SIDE-FILLING MEMBER

(71) Applicant: Panasonic Intellectual Property Management Co., Ltd., Osaka (JP)

(72) Inventors: Yusuke FUKAMOTO, Mie (JP); Yasushi YAMADA, Mie (JP); Yasuaki MAEDA, Mie (JP)

(73) Assignee: Panasonic Intellectual Property Management Co., Ltd., Osaka (JP)

(21) Appl. No.: 17/797,375

(22) PCT Filed: Jan. 29, 2021
(86) PCT No.: PCT/JP2021/003158

§ 371 Date: Aug. 3, 2022

(30) Foreign Application Priority Data
Feb. 4, 2020 (JP) 2020-017382
Apr. 24, 2020 (JP) 2020-077822

(51) Int. Cl. H01L 23/31; H01L 23/29; C08G 59/40; C08G 65/18

(52) U.S. Cl. CPC H01L 23/3185; H01L 23/295; C08G 59/40; C08G 65/18

(57) ABSTRACT

A side-filling resin composition is used to form a side-filling member to be interposed between a base member and a peripheral edge portion of a surface, facing the base member, of a mounted component that is surface-mounted on the base member. The side-filling resin composition has photocurability.

### TECHNICAL FIELD

The present disclosure generally relates to a side-filling resin composition, a semiconductor device, and a method for removing a side-filling member. More particularly, the present disclosure relates to a side-filling resin composition for use to reinforce mounted components such as semiconductor elements, a semiconductor device including a side-filling member made of the side-filling resin composition, and a method for removing the side-filling member.

### BACKGROUND ART

In known semiconductor devices, each including a base member and components mounted on the base member, the gap between the base member and the mounted components is supplied with a resin composition by either filling or applying the resin composition to reinforce connection between the base member and the mounted components. Examples of methods for reinforcing the base member and the mounted components by filling the gap between the base member and the mounted components with a resin composition include a method that uses underfilling and a method that uses side-filling.

According to the method that uses underfilling, the gap between the base member and the mounted components is entirely filled with the resin composition and then the resin composition is cured, thereby sealing the gap between the base member and the mounted components and reinforcing connection between the base member and the mounted components.

On the other hand, according to the method that uses side-filling, the resin composition is applied to only a part of the gap between the base member and the mounted components (e.g., only to peripheral end surfaces of the mounted components in plan view) and then cured, thereby reinforcing the gap between the base member and the mounted components (in particular, the peripheral edge portion of the surface, facing the base member, of the mounted components). Compared to the underfilling member, the side-filling member needs bonding the mounted components to the base member in a smaller area, thus allowing, if any defective components are found while the mounted components are being tested or used, such defective mounted components to be easily removed from the board and replaced with non-defective ones. That is to say, the method that uses side-filling is excellent in so-called “repairability.” Nevertheless, the method that uses side-filling tends to cause a decline in reliability (e.g., reliability about heat resistance) of semiconductor devices.

Patent Literature 1 discloses a liquid epoxy resin composition characterized by containing an epoxy resin, a curing agent, and an inorganic filler, containing, as the inorganic filler, a scale-shaped inorganic substance having an average aspect ratio of 2 to 150 at a content of 0.1% to 30% by mass with respect to the entire epoxy resin composition, and containing the epoxy resin composition with a thixo index of 3.0 to 8.0. Patent Literature 1 discloses a side-filling member that may encapsulate a board and elements installed on the board.

### CITATION LIST

### Patent Literature

Patent Literature 1: JP 2013-102167 A

### SUMMARY OF INVENTION

An object of the present disclosure is to provide a side-filling resin composition having the ability to impart excellent thermal shock resistance to a semiconductor device even if a peripheral edge portion of a surface, facing a base member, of a mounted component of the semiconductor device is reinforced with a side-filling member and ensuring excellent repairability for the side-filling member when defective mounted components need to be repaired. Another object of the present disclosure is to provide a semiconductor device including a side-filling member made of a cured product of the side-filling resin composition and a method for removing the side-filling member.

A side-filling resin composition according to an aspect of the present disclosure is used to form a side-filling member to be interposed between a base member and a peripheral edge portion of a surface, facing the base member, of a mounted component that is surface-mounted on the base member. The side-filling resin composition has photocurability.

A semiconductor device according to another aspect of the present disclosure includes a side-filling member interposed between a base member and a peripheral edge portion of a surface, facing the base member, of a mounted component that has been surface-mounted on the base member. The side-filling member is made of a cured product of the side-filling resin composition described above.

A method for removing a side-filling member according to still another aspect of the present disclosure includes removing the side-filling member of the semiconductor device from between a peripheral edge portion of the mounted component and the base member while heating the side-filling member to a temperature equal to or higher than 200° C.

### BRIEF DESCRIPTION OF DRAWINGS

FIG. 1 is a schematic cross-sectional view illustrating a semiconductor device according to an exemplary embodiment of the present disclosure;

FIG. 2A is a plan view illustrating a first example in which a side-filling member is provided as an interposed member in a peripheral edge portion of a mounted component in the semiconductor device according to the exemplary embodiment;

FIG. 2B is a plan view illustrating a second example in which a side-filling member is provided as an interposed member in a peripheral edge portion of a mounted component in the semiconductor device according to the exemplary embodiment; and

FIG. 2C is a plan view illustrating a third example in which a side-filling member is provided as an interposed member in a peripheral edge portion of a mounted component in the semiconductor device according to the exemplary embodiment.

### DESCRIPTION OF EMBODIMENTS

1. Overview

First, it will be described how the present inventors conceived the concept of the present disclosure.

Using a cured product of the liquid epoxy resin composition of Patent Literature 1 (JP 2013-102167 A) as a side-filling member makes it difficult, when the mounted components mounted on the board include any defective ones that need repairing, to perfectly remove the residue of the side-filling member from the board and the mounted components at the time of the repair. In addition, to reduce the chances of causing conduction failures even when the mounted components on the board of a semiconductor device are exposed to a severe thermal environment as in onboard applications, for example, the thermal shock resistance needs to be improved.

The present inventors carried out extensive research to overcome such a problem. As a result, the present inventors obtained a side-filling resin composition having the ability to impart excellent thermal shock resistance to the semiconductor device even if a peripheral edge portion of a surface, facing the base member, of a mounted component of the semiconductor device is reinforced with the side-filling member and ensuring excellent repairability for the side-filling member when any defective mounted components need to be repaired.

Specifically, a side-filling resin composition according to an exemplary embodiment is used to form a side-filling member 4 to be interposed between a base member 2 and a peripheral edge portion of a surface, facing the base member 2, of a mounted component 3 that is surface-mounted on the base member 2. The side-filling resin composition according to this embodiment has photocurability. As used herein, the “side-filling member” refers to a member made of a material for use to reinforce a mounted component such as a semiconductor element that is surface-mounted on a base member. In this embodiment, the side-filling member 4 is made of a cured product of a side-filling resin composition. It can also be said that the side-filling member 4 is a reinforcing member used to be interposed between the base member 2 and the peripheral edge portion of the surface, facing the base member 2, of the mounted component 3. As used herein, the “peripheral edge portion” of the surface, facing the base member 2, of the mounted component 3 may be the entire peripheral edges of the mounted component 3 in plan view or at least a part of the peripheral edges thereof, whichever is appropriate.

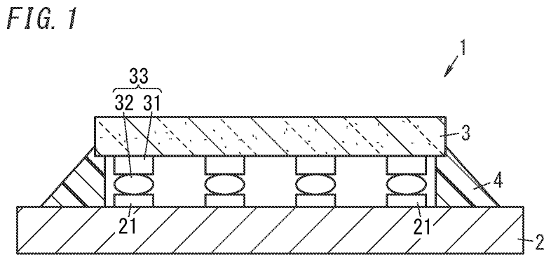

As shown in FIG. 1, the side-filling resin composition according to this embodiment is preferably used in the semiconductor device 1 to form a reinforcing member (i.e., side-filling member 4) to be interposed between the base member 2 and the peripheral edge portion of the surface, facing the base member 2, of the mounted component 3 (such as a semiconductor chip) that is surface-mounted on the base member 2 to reinforce the base member 2 and the mounted component 3.

The side-filling resin composition according to this embodiment has photocurability. A photopolymerizable component having photocurability for use in this embodiment often has a lower viscosity than a thermo-polymerizable component. Thus, even increasing the content of an inorganic filler in the side-filling resin composition is unlikely to cause an increase in the viscosity of the side-filling resin composition. This makes it easier to adjust the coefficient of linear thermal expansion of the cured product to a low level, thus improving the thermal shock resistance of a semiconductor device 1 including a cured product of the side-filling resin composition. Consequently, the semiconductor device 1 including the side-filling member 4 made of the cured product of the side-filling resin composition may have a high degree of reliability about heat resistance.

In addition, if the base member 2 and the mounted component 3 that is surface-mounted on the base member 2 are reinforced with, for example, a cured product of an underfilling resin composition (i.e., an underfilling member) in the semiconductor device 1, then the gap (seam) between the base member 2 and the mounted component 3 will be entirely supplied and filled with the underfilling resin composition to a rather deep point. Then, curing the resin composition reinforces connection between the base member 2 and the mounted component 3. Thus, if the semiconductor device 1 has any defective components that need to be repaired, it would be troublesome to remove the underfilling member that closes the entire gap between the base member 2 and the mounted component 3. In some cases, the base member 2 and the mounted component 3 should be discarded in their entirety. Also, the residue of the side-filling member could be left on the base member 2 and the mounted component 3.

In contrast, the side-filling member according to this embodiment is formed by photo-curing the side-filling resin composition, and therefore, is easily removable by heating. Thus, in the semiconductor device 1 including the side-filling member 4 made of a cured product of the side-filling resin composition according to this embodiment, the side-filling member may have excellent repairability. As used herein, the “repairability” indicates how easily a cured product (which may be any one of an underfilling member or a side-filling member) made of a resin composition in a semiconductor device may be removed from the base member.

Although it is not exactly clear why the side-filling resin composition according to this embodiment has excellent repairability, the reason is presumably as follows. Specifically, the side-filling resin composition according to this embodiment facilitates adjusting the strength of adhesion between the base member 2 (board) of the semiconductor device 1 and the cured product of the side-filling resin composition. Thus, when the side-filling member formed on the board out of the cured product of the side-filling resin composition is removed, the residue of the side-filling member is easily removable from the board and the mounted component. This is presumably the reason why the side-filling resin composition has excellent repairability.

As can be seen, according to this embodiment, the cured product of the side-filling resin composition is easily removable by heating. Thus, the side-filling resin composition according to this embodiment makes the semiconductor device 1 easily repairable even if the semiconductor device 1 comes to have any defective components.

Note that the side-filling resin composition according to this embodiment has photocurability, and therefore, may shorten, compared to a thermosetting resin component, the takt time (e.g., the time it takes to form the cured product) when the peripheral edge portion of the surface, facing the base member 2, of the mounted component 3 is reinforced with the cured product of the side-filling resin composition in the gap between the base member 2 and the mounted component 3 that is surface-mounted on the base member 2. In addition, the side-filling resin composition according to this embodiment may also reduce the air bubbles produced before and after the curing, compared to the thermosetting resin component. This may reduce the chances of producing voids in the cured product. Consequently, this reduces, even if the peripheral edge portion of the surface, facing the base member 2, of the mounted component 3 is reinforced with the side-filling resin composition, the chances of causing defects in the semiconductor device 1. Furthermore, the side-filling resin composition does not have to be heated to be cured, and therefore, the side-filling member 4 is less likely to be affected by the thermal history due to heating. Thus, the side-filling resin composition may not only reinforce the base member 2 and the peripheral edge portion, facing the base member 2, of the mounted component 3 by making the mounted component 3 less easily separable in the semiconductor device 1 but also reduce the chances of causing conduction failures in the semiconductor device 1. Therefore, reinforcing the base member 2 and the mounted component 3 with the side-filling resin composition interposed between the base member 2 and the peripheral edge portion of the surface, facing the base member 2, of the mounted component 3 that is surface-mounted on the base member 2 in the semiconductor device 1 enables forming the side-filling member 4 in a short time and reducing the chances of leaving a thermal history in the side-filling member 4. Consequently, the reinforcing member made of the side-filling resin composition is hardly warped and rarely produces voids.

As can be seen, the side-filling resin composition according to this embodiment may reinforce connection between the base member 2 and the mounted component 3 in the gap between the base member 2 of the semiconductor device 1 and the peripheral edge portion of the surface, facing the base member 2, of the mounted component 3 mounted on the base member 2. More specifically, the side-filling resin composition is allowed to have these advantageous properties by appropriately adjusting the respective components of the composition to be described below.

2. Details

Next, components that may be included in the side-filling resin composition according to this embodiment and the properties of the side-filling resin composition will be described more specifically.

The side-filling resin composition according to this embodiment preferably includes a photocurable component (A) and a photopolymerization initiator (B). This may impart photocurability to the side-filling resin composition easily. In addition, the side-filling member 4 formed by photo-curing the side-filling resin composition is removable more easily by heating than a cured product of a thermosetting component. Thus, the semiconductor device 1 including the side-filling member 4 made of a cured product of the side-filling resin composition according to this embodiment has a high degree of thermal shock resistance. In addition, the side-filling member 4 of the semiconductor device 1 may have excellent repairability. In particular, in the known art, when a side-filling member is formed out of a cured product of a thermosetting component, an additive such as a flexibility imparting agent is added thereto to improve its repairability. In that case, however, addition of the flexibility imparting agent tends to cause a decline in thermal properties such as heat resistance and thermal shock resistance. In contrast, the side-filling resin composition according to this embodiment includes a cured product of the side-filling resin composition, thus allowing the semiconductor device 1 to have excellent thermal shock resistance. In addition, the side-filling member 4 may have excellent repairability even if no additive such as a flexibility imparting agent is added thereto.

[Photopolymerizable Component (A)]

The photopolymerizable component (A) may impart photocurability to the side-filling resin composition. Examples of the photopolymerizable component (A) include a compound having appropriate photocurability. Specifically, examples of such compounds having photocurability include cationic polymerizable compounds and radical polymerizable compounds.

The proportion by mass of the photocurable component (A) to the total solid content of the side-filling resin composition is preferably equal to or greater than 10% by mass and equal to or less than 60% by mass. This would impart an even higher degree of photocurability to the side-filling resin composition. The proportion by mass of the photocurable component (A) to the total solid content of the side-filling resin composition is more preferably equal to or greater than 15% by mass and equal to or less than 55% by mass, and even more preferably equal to or greater than 20% by mass and equal to or less than 50% by mass.

The photopolymerizable component (A) preferably contains a photo-cationic polymerizable compound (A1). That is to say, the side-filling resin composition preferably contains the photo-cationic polymerizable compound (A1). In that case, even if the base member 2 and the mounted component 3 are reinforced by interposing the cured product of the side-filling resin composition between the base member 2 of the semiconductor device 1 and the peripheral edge portion of the surface, facing the base member 2, of the mounted component 3, the cured product is still easily removable by heating. Thus, the side-filling resin composition may impart even better repairability to the semiconductor device 1. In addition, if the side-filling resin composition contains the photo-cationic polymerizable compound (A1), high reliability will be achieved in a heat cycle when the base member 2 and the mounted component 3 are reinforced with the cured product of the side-filling resin composition in the semiconductor device 1. As used herein, the “heat cycle” refers to a temperature cycle in which heating and cooling are alternately repeated between a low temperature range (e.g., —40° C.) and a high temperature range (e.g., 125° C.).

The photo-cationic polymerizable compound (A1) is, for example, a component that produces a cation species due to the action of the photopolymerization initiator (B) when irradiated with light and may polymerize the cation species as a growing chain. The photopolymerization initiator (B) preferably contains a photo-cationic polymerization initiator (B1). The photo-cationic polymerization initiator (B1) preferably has the function of a photoacid generator. As used herein, the “photoacid generator” refers to a compound having the function of absorbing, and thereby decomposing, the light radiated to generate an acid and polymerize the photopolymerizable component.

The photo-cationic polymerizable compound (A1) preferably contains at least one selected from the group consisting of an epoxy resin, an oxetane resin, and a vinyl ether resin.

The epoxy resin may be, for example, a compound having at least one epoxy group in one molecule. Specifically, the epoxy resin may be at least one compound selected from the group consisting of biphenyl epoxy resins, bisphenol A epoxy resins, bisphenol F epoxy resins, bisphenol S epoxy resins, naphthalene ring-containing epoxy resins, anthracene ring-containing epoxy resins, alicyclic epoxy resins, dicyclopentadiene epoxy resins having a dicyclopentadiene skeleton, phenol novolac epoxy resins, cresol novolac epoxy resins, triphenylmethane epoxy resins, brome-containing epoxy resins, aliphatic epoxy resins, aliphatic polyether epoxy resins, and triglycidyl isocyanurate. The epoxy resin may have a glycidyl group.

The oxetane resin may be, for example, a compound having at least one oxetane skeleton in one molecule. Specifically, the oxetane resin may be at least one compound selected from the group consisting of 3-ethyl-3-hydroxymethyl oxetane, 2-ethylhexyl oxetane, 3-ethyl-3-(2-ethylhexyloxymethyl) oxetane, 3-ethyl-3-(cyclohexyloxy)methyl oxetane, and 3-ethyl-3-(phenoxymethyl) oxetane.

The vinyl ether resin may be, for example, a compound having at least one vinyl ether skeleton in one molecule. Specifically, the vinyl ether resin may be at least one compound selected from the group consisting of ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, bisphenol A alkylene oxide divinyl ether and bisphenol F alkylene oxide divinyl ether.

If the photopolymerizable component (A) contains the photo-cationic polymerizable compound (A1), then the photo-cationic polymerizable compound (A1) preferably contains an epoxy resin and an oxetane resin. This enables advancing the photocuring of the side-filling resin composition more smoothly. If the photo-cationic polymerizable compound (A1) contains an epoxy resin and an oxetane resin, the proportion by mass of the epoxy resin to the total content of the epoxy resin and the oxetane resin is preferably equal to or greater than 5% by mass and equal to or less than 95% by mass. This enables advancing the photocuring of the side-filling resin composition even more smoothly. Note that the photo-cationic polymerizable compound (A1) is not limited to the above-described one but may also be a monomer having appropriate cation polymerizability and an oligomer.

The proportion by mass of the photo-cationic polymerizable compound (A1), which is contained in the photocurable component (A), to the entire photocurable component (A) is preferably equal to or greater than 5% by mass and equal to or less than 100% by mass.

Also, the proportion by mass of the oxetane resin, which is contained in the photo-cationic polymerizable compound (A1), to the entire photocurable component (A) is preferably equal to or greater than 5% by mass and equal to or less than 100% by mass.

Furthermore, the proportion by mass of the oxetane resin, which is contained in the photocurable component (A), to the entire photocurable component (A) is preferably equal to or greater than 5% by mass and equal to or less than 100% by mass.

Furthermore, the proportion by mass of the vinyl ether resin, which is contained in the photocurable component (A), to the entire photocurable component (A) is preferably equal to or greater than 0% by mass and equal to or less than 30% by mass.

Note that the components that may be included in the photopolymerizable components (A) of the side-filling resin composition are not limited to the above-described ones but may further include resins other than the above-described ones.

[Photopolymerization Initiator (B)]

The photopolymerization initiator (B) may promote the curing reaction of the photocurable components (e.g., the photopolymerizable component (A) in this embodiment) in the side-filling resin composition.

The photopolymerization initiator (B) preferably contains a cationic photopolymerization initiator (B1). That is to say, the side-filling resin composition preferably contains the cationic photopolymerization initiator (B1). This would further improve the repairability of the side-filling member 4, made of the side-filling resin composition, in the semiconductor device 1. Among other things, the side-filling resin composition particularly preferably contains the photo-cationic polymerizable compound (A1) and the cationic photopolymerization initiator (B1). This makes it even easier to remove the side-filling member 4 made of the cured product of the side-filling resin composition from the semiconductor device 1. The reason is presumably as follows. Specifically, curing the side-filling resin composition containing the photo-cationic polymerizable compound (A1) and the cationic photopolymerization initiator (B1) causes an acid component, produced as a byproduct from the cationic photopolymerization initiator (B1), to remain in the cured product. Then, heating the cured product to an even higher temperature causes the acid component described above to react to the cured product, thus producing pyrolysis of the cured product. This causes a decline in the physical properties of the cured product to make the cured product peelable more easily. This is presumably because the side-filling member 4 is easily removable from the semiconductor device 1.

If the side-filling resin composition contains the cationic photopolymerization initiator (B1), then the proportion by mass of the cationic photopolymerization initiator (B1) to the photopolymerizable component (A) is preferably equal to or greater than 0.01% by mass and equal to or less than 5% by mass, more preferably equal to or greater than 0.1% by mass and equal to or less than 3% by mass, and even more preferably equal to or greater than 0.5% by mass and equal to or less than 2% by mass.

[Inorganic Filler (C)]

The side-filling resin composition preferably further contains an inorganic filler (C). Adding the inorganic filler (C) to the side-filling resin composition may lower the coefficient of thermal expansion (CTE) of a cured product of the side-filling resin composition. This may reduce the chances of causing warpage to the side-filling member 4, even if the base member 2 and the mounted component 3 are reinforced with a cured product of the side-filling resin composition by interposing the side-filling resin composition between the base member 2 of the semiconductor device 1 and the peripheral edge portion of the surface, facing the base member 2, of the mounted component 3. This may further reduce failures to be caused by generation of heat in the semiconductor device 1.

If the side-filling resin composition contains the inorganic filler (C), the proportion by mass of the inorganic filler (C) to the total solid content of the side-filling resin composition is preferably equal to or greater than 30% by mass and equal to or less than 90% by mass. This makes it easier to further lower the CTE of the cured product of the side-filling resin composition. The proportion by mass of the inorganic filler (C) to the total solid content of the side-filling resin composition is more preferably equal to or greater than 40% by mass and equal to or less than 80% by mass, and is even more preferably equal to or greater than 50% by mass and equal to or less than 75% by mass.

The inorganic filler (C) contains at least one material selected from the group consisting of, for example, silica, alumina, clay, mica, talc, aluminum hydroxide, magnesium hydroxide, calcium carbonate, and glass. The silica may be, for example, molten silica, crystalline silica, or fumed silica.

If the inorganic filler (C) contains silica, then the silica may be subjected to surface treatment. Subjecting the silica to surface treatment makes the silica easily compatible with the photocurable component in the side-filling resin composition, thus increasing the degree of dispersion of the side-filling resin composition. The silica may be subjected to surface treatment by treating the silica with a silane coupling agent, for example. The silane coupling agent may be, for example, a compound including at least one functional group selected from the group consisting of, for example, an epoxy group, an amino group, a (meth)acryloyl group, and a phenyl group.

The inorganic filler (C) preferably has a mean particle size equal to or greater than 2.5 μm and equal to or less than 200 μm, for example. Setting the mean particle size of the inorganic filler (C) within this range allows the side-filling resin composition, which is interposed between the base member 2 and the peripheral edge portion of the surface, facing the base member 2, of the mounted component 3, to maintain even better flowability. As used herein, the “mean particle size” refers to a median diameter D50. The median diameter D50 is calculated based on a particle size distribution obtained by measurement by the laser diffraction and scattering method. The particle size distribution may be measured with, for example, laser diffraction particle size analyzer.

[Other Components]

The side-filling resin composition may contain any additional components other than the above-described ones unless the advantages of the present disclosure are impaired. For example, the side-filling resin composition may contain additional resin components other than the resin components described above.

Optionally, the sealing resin composition may contain any appropriate additive. Examples of the additives include a curing agent, a flux, a viscosity modifier, a surface conditioner, a silane coupling agent, an antifoaming agent, a leveling agent, a low stress agent, and a pigment. For example, the side-filling resin composition may contain a thixotropic property imparting agent. This makes it easier to allow, when supplying the side-filling resin composition to the gap between the base member 2 of the semiconductor device 1 and the peripheral edge portion of the surface, facing the base member 2, of the mounted component 3, the side-filling resin composition to maintain even better flowability and thixotropic property. This allows the side-filling resin composition to have even higher moldability. Consequently, this enables, even if the side-filling member 4 for reinforcing the peripheral edge portion of the mounted component 3 is formed of the side-filling resin composition, imparting excellent strength to the side-filling member 4.

It is also preferable that the side-filling resin composition contain a photosensitizer. This may promote the curing reaction of the side-filling resin composition. Consequently, this may shorten the takt time when forming a cured product out of the side-filling resin composition.

The side-filling resin composition preferably contains no organic solvent or has an organic solvent content equal to or less than 0.5% by mass.

The side-filling resin composition may be obtained by, for example, compounding the above-described components together with an appropriate additive added to the mixture as needed. Specifically, the side-filling resin composition may be prepared by the following method, for example.

First, the components that may be included in the side-filling resin composition described above are compounded together either simultaneously or sequentially to obtain a mixture. The mixture is stirred up and homogenized while being subjected to heating or cooling treatment as needed.

Next, an additive is added as needed to the mixture, which is stirred up again and further homogenized until the respective components are dispersed uniformly in the resultant mixture while being subjected to heating or cooling treatment as needed. In this manner, the side-filling resin composition may be obtained. To stir up the mixture, a disper, a planetary mixer, a ball mill, a three-roll, a bead mill, or any other suitable mixer may be used in an appropriate combination as needed.

The side-filling resin composition preferably has a viscosity of 1000 Pa s or less at 25° C. This makes it easier to ensure sufficient moldability for the side-filling resin composition. In addition, in that case, sufficient fillability would be achieved between the base member 2 and the peripheral edge portion of the surface, facing the base member 2, of the mounted component 3 such as a semiconductor chip. The viscosity of the side-filling resin composition at 25° C. may be measured with a Type B viscosimeter under the condition including a rotor No. 7, the number of revolutions of 1 to 50 rpm, and a measuring time of 60 to 180 seconds. The viscosity of the side-filling resin composition at 25° C. is more preferably equal to or less than 500 Pa·s and even more preferably equal to or less than 200 Pa·s.

The side-filling resin composition preferably has a thixo index of 2 or more at 25° C. This makes it easier to ensure sufficient moldability for the side-filling resin composition. The side-filling resin composition more preferably has a thixo index of 3 or more at 25° C. The thixo index of the side-filling resin composition at 25° C. may be calculated by dividing the viscosity value measured with a Type B viscosimeter under the condition including a rotor No. 7 and the number of revolutions of 1 rpm, by the viscosity measured at the number of revolutions of 10 rpm.

The side-filling resin composition according to this embodiment has photocurability as described above. Thus, the side-filling resin composition may be cured when irradiated with light. The light irradiation condition, including the wavelength of the light radiated, the intensity of the light radiated (i.e., the quantity of the light radiated), and the duration of the light radiated, may be adjusted appropriately according to the types of the components (such as the photocurable component (A)) that may be included in the side-filling resin composition and the type of the polymerization initiator (such as the photopolymerization initiator (B)). Any appropriate light source may be adopted as a light source for irradiating the side-filling resin composition with light. The light source may be at least one type of light source selected from the group consisting of a chemical lamp, a low-pressure mercury lamp, a medium-pressure mercury lamp, a high-pressure mercury lamp, an ultrahigh pressure mercury lamp, a xenon lamp, a metal halide lamp, an LED, a YAG, a g-line (with a wavelength of 436 nm), an h-line (with a wavelength of 405 nm), an i-line (with a wavelength of 365 nm), and combination of two or more types selected from the g-line, the h-line, and the i-line. However, the light source does not have to be one of these light sources but may also be any other light source that may irradiate, and thereby cure, the side-filling resin composition with an ultraviolet ray.

A cured product of the side-filling resin composition preferably has a glass transition temperature (Tg) equal to or higher than 130° C. Setting the glass transition temperature at a temperature equal to or higher than 130° C. allows the cured product of the side-filling resin composition to have heat resistance. The glass transition temperature may be measured by thermomechanical analysis (TMA), for example. In addition, setting the glass transition temperature at a temperature equal to or higher than 130° C. may reduce the chances of the cured product of the side-filling resin composition being softened even in a high-temperature range (of around 125° C., for example) in a heat-cycle test. This allows the side-filling resin composition to ensure high reliability about heat resistance for the semiconductor device 1. Among other things, if the mounted component on the board is reinforced with a side-filling member made of a cured product of a known resin composition in the semiconductor device 1, exposing the semiconductor device 1 to a severe thermal environment (e.g., at a temperature of ˜40° C. or less or 125° C. or more) would often cause conduction failures between the board and the mounted component. In contrast, forming the side-filling member to reinforce the mounted component 3 on the base member 2 in the semiconductor device 1 out of the side-filling resin composition according to this embodiment allows the cured product of the side-filling resin composition to impart high thermal shock resistance to the semiconductor device 1.

It is also preferable that the cured product of the side-filling resin composition have a coefficient of thermal expansion (CTE) less than 40 ppm/° C. at a temperature equal to or lower than the glass transition temperature Tg. This may reduce not only the chances of causing warpage to the side-filling member 4 made of the cured product of the side-filling resin composition but also the chances of causing peeling of the cured product of the side-filling resin composition from the base member 2 and the mounted component 3 at a temperature equal to or lower than the glass transition temperature. Consequently, this may reduce the chances of causing cracks in the cured product of the sealing resin composition. Thus, the side-filling member 4 made of the side-filling resin composition may further improve the reliability of the semiconductor device 1 about the heat resistance thereof. The CTE of the cured product of the side-filling resin composition at a temperature equal to or lower than Tg is more preferably equal to or less than 35 ppm/° C. and is even more preferably equal to or less than 30 ppm/° C. or less. The CTE of the cured product of the side-filling resin composition at a temperature equal to or lower than Tg is obtained by calculating the gradient of a tangential line based on a variation in dimension between two arbitrary temperatures that are equal to or lower than Tg.

The cured product of the side-filling resin composition preferably has a shear strength equal to or greater than 3 MPa at 125° C. and a shear strength less than 0.1 MPa at 200° C. Setting the shear strength of the cured product at 125° C. at a value equal to or greater than 3 MPa reduces the chances of causing a decline in the adhesion strength of the cured product until the temperature reaches a temperature range around Tg of the cured product, thus enabling reducing the stress applied to solder bumps due to thermal shock. That is to say, this may reduce the chances of causing a variation in dimensions of the cured product of the side-filling resin composition due to heating. Thus, the side-filling resin composition according to this embodiment may impart better reliability about heat resistance to the semiconductor device 1 in a temperature cycle (heat cycle) from around −40° C. in a low temperature range to around 125° C. in a high temperature range, for example. On the other hand, if the shear strength at 200° C. is less than 0.1 MPa, the cured product of the side-filling resin composition will have decreased adhesion strength at a temperature for repairing (e.g., at a heating temperature of around 240° C.). This allows, when the semiconductor device 1 with defects is repaired, only defective components to be replaced. That is to say, the semiconductor device 1 may be repaired by easily removing the cured product of the side-filling resin composition from the base member 2 of the semiconductor device 1. Thus, the cured product of the side-filling resin composition according to this embodiment ensures excellent repairability. In the cured product of the side-filling resin composition according to this embodiment, its shear strength is the adhesion strength, measured with a bond tester, of the cured product to the substrate in a situation where the side-filling resin composition is allowed to be cured on a glass epoxy substrate that has been subjected to a solder resist process. Specifically, the shear strength of the side-filling resin composition may be obtained in the following manner. First, a solder resist layer is formed on an appropriate glass epoxy substrate. More specifically, in this embodiment, the glass epoxy substrate may be FR4 (name of a product manufactured by Panasonic Corporation and having a thickness of 0.6 mm). The solder resist layer is made of an appropriate solder resist composition. Specifically, the solder resist layer is formed by curing the solder resist composition by UV curing or thermal curing, for example, and then subjecting the solder resist composition to development process such as alkali development as needed. The solder resist composition may be, for example, a two-component liquid solder resist composition, including an active energy ray curable resin obtained by, for example, adding a saturated or unsaturated polybasic acid anhydride to a product of reaction between a novolac epoxy compound and an unsaturated monocarboxylic acid, a photopolymerization initiator, a diluent, and an epoxy compound. Specifically, the solder resist composition may be formed out of a resist PSR4000 manufactured by Taiyo Ink Mfg. Co., Ltd., for example Note that this is not the only method for forming the solder resist layer. For example, the solder resist composition may be a single-component type or a two-component type, whichever is appropriate. Also, the solder resist composition may be cured by thermal curing, phot-curing, or thermal curing and photo-curing in combination. Furthermore, the solder resist composition may be in a liquid form or in the form of a dry film, whichever is appropriate. The glass epoxy substrate may be coated with the solder resist layer by treating the surface of the glass epoxy substrate with this resist. Subsequently, the side-filling resin composition is applied onto the solder resist layer and then photo-cured, thereby forming a cured product of the side-filling resin composition on the solder resist layer. The condition for photo-curing the side-filling resin composition may be appropriately adjusted according to the components that may be included in the side-filling resin composition as described above. The condition for curing the side-filling resin composition to measure the shear strength of the cured product of the side-filling resin composition includes a wavelength of radiated light of 365 nm, an intensity of light radiated (i.e., a quantity of light radiated) of 1000 mW/cm², and an irradiation time of 4 seconds. Subsequently, the adhesion strength between the cured product and the solder resist layer when the solder resist layer on the glass epoxy substrate and the cured product on the solder resist layer are heated to either 125° C. or 200° C. is measured with a bond tester. The condition for measurement includes a test height (i.e., the distance between the surface of the substrate and the tip of a measuring jig) of 50 μm and a test speed of 500 μm/s. A sample for measurement is a circular columnar cured product having a diameter of 3 mm and a height of 1 mm. Heating is controlled by the stage temperature of the equipment. In this manner, the shear strength of the cured product of the side-filling resin composition may be obtained. As the bond tester, a measuring instrument such as Nordson DAGE 4000 Optima (name of a product manufactured by Nordson Advanced Technology K. K. Japan) may be used, for example. Note that the above-described condition is a condition for measuring the shear strength of the cured product of the side-filling resin composition as defined by this embodiment. That is to say, the foregoing description should not be construed that the target to which the side-filling resin composition is applied is limited to the solder resist layer.

The side-filling resin composition according to this embodiment is preferably used as a side-filling member as described above. The side-filling resin composition may be used particularly preferably as a side-filling member to be supplied in a late stage of a flip-chip bonding process.

[Semiconductor Device]

As described above, the side-filling resin composition according to this embodiment is preferably used to form the side-filling member 4 to reinforce the base member 2 and the mounted component 3 in the semiconductor device 1. In particular, the side-filling resin composition may reinforce the base member 2 and the mounted component 3 just by supplying the side-filling resin composition to the gap between the base member 2 and the peripheral edge portion of the surface, facing the base member 2 of the mounted component 3 to make the mounted component 3 hardly peelable unintentionally by reinforcing the base member 2 and the mounted component 3 and to reduce the chances of causing conduction failures. Thus, compared to the underfilling material to be supplied to the entire gap between the base member 2 and the mounted component 3, the amount of the resin composition to supply may be reduced. In addition, to repair the semiconductor device 1 when a contact failure has occurred between the base member 2 and the mounted component 3 in the semiconductor device 1, only the side-filling member 4 that supports the base member 2 and the mounted component 3 (specifically, the side-filling member 4 interposed in the peripheral edge portion of the mounted component 3) needs to be peeled off. This allows the semiconductor device 1 to be repaired without discarding members that operate properly. In addition, the side-filling member 4 according to this embodiment is easily removable even without being heated to an excessively high temperature. Thus, the side-filling member 4 made of the side-filling resin composition according to this embodiment ensures excellent repairability for the semiconductor device 1. Furthermore, this may reduce, when the semiconductor device 1 is repaired, the chances of discarding properly operating components other than defective components as described above, thus contributing to cutting down the cost in cases of failures, compared to the underfilling material.

A semiconductor device 1 according to this embodiment includes the base member 2, the mounted component 3, and the side-filling member 4. The mounted component 3 is surface-mounted on the base member 2. The side-filling member 4 is interposed between the base member 2 and the peripheral edge portion of the surface, facing the base member 2, of the mounted component 3. The side-filling member 4 is made of the cured product of the side-filling resin composition described above.

FIG. 1 illustrates an exemplary semiconductor device 1 according to this embodiment. The semiconductor device 1 includes: the base member 2 for supporting the mounted component 3 such as a semiconductor chip; the mounted component 3 that is surface-mounted face down on the base member 2; and the side-filling member 4 interposed between the base member 2 and the mounted component 3, more specifically, between the base member 2 and the peripheral edge portion of the surface, facing the base member 2, of the mounted component 3. The side-filling member 4 may support the base member 2 and the mounted component 3 in the gap between the base member 2 and the peripheral edge portion of the mounted component 3.

The side-filling member 4 is formed by supplying the side-filling resin composition to part or all of the base member 2 and the peripheral edge portion of the surface, facing the base member 2, of the mounted component 3 between the base member 2 and the mounted component 3 and then photo-curing the side-filling resin composition. The distance to which the side-filling resin composition is allowed to infiltrate inside the peripheral edge portion of the surface, facing the base member 2, of the mounted component 3 between the base member 2 and the mounted component 3 in plan view may be appropriately adjusted. For example, the infiltration distance is preferably greater than 0% and equal to or less than 5% of the length of the mounted component 3. As used herein, the “infiltration distance” refers to the length to which the side-filling resin composition has infiltrated inward from an outer periphery of the mounted component 3 in plan view to some internal point on the surface, facing the base member 2, of the mounted component 3.

Next, a semiconductor device 1 and a method for fabricating the semiconductor device 1 will be described.

The semiconductor device 1 includes: the base member 2 including conductor wiring 21; the mounted component 3 such as a semiconductor chip including bump electrodes 33 and mounted onto the base member 2 by having the bump electrodes 33 bonded onto the conductor wiring 21; and the side-filling member 4. The side-filling member 4 is a cured product of the side-filling resin composition described above.

The base member 2 may be a motherboard, a package board, or an interposer board, for example. In this embodiment, the base member 2 includes an insulating substrate made of glass epoxy, polyimide, polyester, a ceramic, or any other suitable material and the conductor wiring 21 made of an electrical conductor such as copper and formed on its surface. The conductor wiring 21 includes electrode pads, for example.

The mounted component 3 may be a semiconductor chip, for example. The semiconductor chip may be a flip-chip bonded chip such as a ball-grid array (BGA), land-grid array (LGA), or chip size package (CSP) chip. Alternatively, the semiconductor chip may also be a package on package (PoP) chip.

The mounted component 3 may include a plurality of bump electrodes 33. Each of the bump electrodes 33 includes solder. As shown in FIG. 1, each bump electrode 33 includes a pillar 31 and a solder bump 32 provided at the tip of the pillar 31. The solder bump 32 is made of solder, and therefore, each bump electrode 33 includes solder. The pillar 31 may be made of copper, for example.

The melting point of the solder contained in each bump electrode 33 (e.g., the solder of the solder bump 32 thereof) is not limited to any particular value but may be set at any temperature as long as the solder may be melted at a temperature equal to or lower than the mounting temperature (of 200° C. to 260° C., for example) when the mounted component 3 such as a semiconductor chip is mounted. Also, the composition of the solder is not limited to any particular one but may be an appropriate composition. For example, the solder may be, for example, an Sn—Ag based solder or an Sn—Ag—Cu based solder. Note that the bump electrode 33 including solder does not have to have the structure described above but may include only a spherical solder bump 32 (solder ball), for example. That is to say, the bump electrode 33 does not have to include the pillar.

In the semiconductor device 1 shown in FIG. 1, the gap between the base member 2 and the mounted component 3 is partially filled with the side-filling member 4 in only a region between the base member 2 and the peripheral edge portion of the surface, facing the base member 2, of the mounted component 3. This allows the side-filling member 4 to reinforce the mounted component 3, which is surface-mounted on the base member 2, in a peripheral edge portion of the mounted component 3.

An exemplary method for fabricating the semiconductor device 1 will be described. Note that the method for fabricating the semiconductor device 1 to be described below is only an example and should not be construed as limiting. Rather, any other method may also be adopted as long as the method allows the semiconductor device 1 to be fabricated by supplying the above-described side-filling resin composition to be interposed to cover part or all of the peripheral edge portion of the surface, facing the base member 2, of the mounted component 3 that is surface-mounted on the base member 2.

First, a base member 2 including conductor wiring 21 and a mounted component 3 including bump electrodes 33 are provided. The mounted component 3 is placed on the base member 2 and the bump electrodes 33 are arranged on the conductor wiring 21. The conductor wiring 21 and the bump electrodes 33 may be electrically connected together by heating, for example.

Subsequently, the side-filling resin composition is supplied onto the peripheral edge portion of the surface, facing the base member 2, of the mounted component 3 that is surface-mounted on the base member 2. Then, the side-filling resin composition thus supplied is irradiated with light, and thereby cured. In this manner, the side-filling member 4 is formed on the base member 2 and on the peripheral edge portion, facing the base member 2, of the mounted component 3. The condition for curing the side-filling resin composition is as described above.

These process steps do not have to be performed exactly in the above-described order. Rather, as long as the side-filling resin composition interposed may be placed during the manufacturing process to eventually cover the base member 2 and the peripheral edge portion of the surface, facing the base member 2, of the mounted component 3 either only partially or entirely, the side-filling resin composition may be placed at any timing during the manufacturing process anywhere on the mounted component 3 and the base member 2.

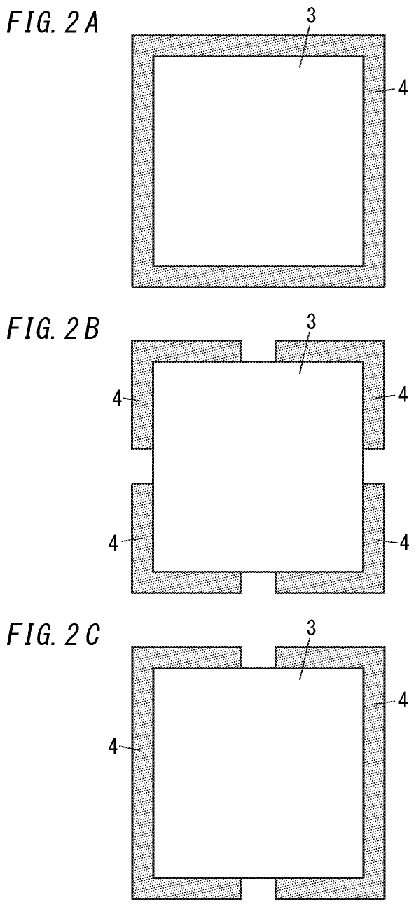

Specific exemplary regions where the side-filling member 4 may be placed in the semiconductor device 1 will be described with reference to FIGS. 2A-2C. Note that these are only exemplary regions where the side-filling member 4 may be placed in the semiconductor device 1.

In FIGS. 2A to 2C, the side-filling member 4 is formed in the semiconductor device 1 by supplying the side-filling resin composition to the gap between the base member 2 and the peripheral edge portion (in plan view) of the surface, facing the base member 2, of the mounted component 3 that is surface-mounted on the base member 2 and then curing the side-filling resin composition. That is to say, FIGS. 2A-2C illustrate three examples (hereinafter referred to as first, second, and third example, respectively) in which the base member 2 and the peripheral edge portion of the mounted component 3 are reinforced with the side-filling member 4. In the semiconductor device 1 shown in FIGS. 2A-2C, the side-filling resin composition is not supplied to the depth of the gap between the base member 2 and the mounted component 3 (e.g., the entire lower surface, including the central area, of the mounted component 3). The side-filling resin composition according to this embodiment is supplied to only the peripheral edge portion of the mounted component 3 but may still reinforce the base member 2 and the mounted component 3 of the semiconductor device 1. In particular, the side-filling member 4 made of the side-filling resin composition supports the peripheral edge portion of the mounted component 3 in the semiconductor device 1. This may reduce the chances of the mounted component 3 being warped.

In the first example illustrated in FIG. 2A, the side-filling member 4 made of a cured product of the side-filling resin composition is formed to cover the entire peripheral edges of the surface, facing the base member 2, of the mounted component 3. This may increase the strength of the portion that reinforces the base member 2 and the mounted component 3 of the semiconductor device 1, thus further reducing the chances of causing warpage to the base member 2 and the mounted component 3. In addition, this also makes it easier, than in the case of the underfilling material, to repair the semiconductor device 1 when the semiconductor device 1 comes to have any defective components.

In the second example illustrated in FIG. 2B, the side-filling member 4 made of a cured product of the side-filling resin composition is formed to cover a plurality of corner portions (more specifically, portions including the four corners of the mounted component 3 which is generally rectangular in plan view) in the peripheral edge portion of the surface, facing the base member 2, of the mounted component 3. This may maintain the strength of the portions that reinforce the base member 2 and the mounted component 3 of the semiconductor device 1, thus reducing the chances of causing warpage to the base member 2 and the mounted component 3. In addition, this also makes it easier, than in the case of the underfilling material, to repair the semiconductor device 1 when the semiconductor device 1 comes to have any defective components.

In the third example illustrated in FIG. 2C, the side-filling member made of a cured product of the side-filling resin composition is formed to cover the corner portions and two opposing sides of the surface, facing the base member 2, of the mounted component 3. This may maintain the strength of the portions that reinforce the base member 2 and the mounted component 3 of the semiconductor device 1, thus reducing the chances of causing warpage to the base member 2 and the mounted component 3. In addition, this also makes it easier, than in the case of the underfilling material, to repair the semiconductor device 1 when the semiconductor device 1 comes to have any defective components.

Next, a method for removing the side-filling member according to this embodiment will be described.

A method for removing the side-filling member according to this embodiment includes removing the side-filling member 4 from between the peripheral edge portion of the mounted component 3 and the base member 2 with the side-filling member of the semiconductor device 1 heated to a temperature equal to or higher than 200° C. Repairing a defective part of the semiconductor device 1 requires melting the solder material such as the solder bumps 32 to electrically disconnect the base member 2 and the mounted component 3 from each other. According to this embodiment, the side-filling member 4 may be removed by heating the side-filling member 4 to a temperature equal to or higher than the melting temperature (of approximately 200° C.) of the solder material. Thus, the method for removing the side-filling member 4 according to this embodiment allows the semiconductor device 1 to be repaired easily.

### EXAMPLES

Next, specific examples of the present disclosure will be presented. Note that the following are only examples of the present disclosure and should not be construed as limiting.

1. Preparation of Side-Filling Resin Composition

### First to Ninth Examples and First to Third Comparative Examples

The respective components shown in Table 1 (to be posted at the end of this section) were compounded together at the respective ratios (parts by mass) shown in Table 1, loaded into a planetary mixer, stirred up and mixed, and then uniformly dispersed with three rolls, thereby obtaining resin compositions. Following are the details of the components shown in Table 1:

(Photopolymerizable Components)
Epoxy resin 1: product name EPICLON 840A manufactured by DIC Corporation;
Epoxy resin 2: product name CELLOXIDE 2021 manufactured by Daicel Corporation;
Epoxy resin 3: product name EX-192 manufactured by Nagase ChemteX Corporation; and
Oxetane resin: product name OXT-221 manufactured by Toagosei Co., Ltd. (Photopolymerization initiator)
Photopolymerization initiator 1: product name CPI-200K manufactured by Sun-Apro Ltd.; and
Photopolymerization initiator 2: WPI-170 manufactured by FUJIFILM Wako Pure Chemical Corporation.

(Others (Such as Additives))
Photosensitizer: product name 2-Isopropylthioxanthone manufactured by FUJIFILM Wako Pure Chemical Corporation;
Thermosetting agent 1: acid anhydride (product name B650 manufactured by DIC Corporation);
Thermosetting agent 2: imidazole (2MAOK manufactured by Shikoku Chemicals Corporation);
Inorganic filler: product name QS-6 (cut at 30 μm) manufactured by Denka Co., Ltd.;
Thixotropic property imparting agent: product name RY200 manufactured by Nippon Aerosil Co., Ltd.; and
Flexibility imparting agent: product name LBR-302 manufactured by Kuraray Co., Ltd.

2. Evaluation Tests

2.1. Glass Transition Temperature and Loss Modulus (Elastic Modulus when Heated)

In the first to ninth examples, the side-filling resin composition prepared as described in the item 1. was irradiated with light for 4 seconds by an LED UV irradiator (model number Aicure UD40 manufactured by Panasonic Industrial Device SUNX Co., Ltd.) under the condition including an illuminance of 1000 mW/cm² and thereby cured. The cured product of the side-filling resin composition thus obtained was cut into multiple test pieces each having a width of 5 mm, a length of 50 mm, and a thickness of 0.2 mm. In the first to third comparative examples, the side-filling resin composition was heated under the condition including a heating temperature of 150° C. and a heating duration of 1 hour and thereby cured. The cured product of the side-filling resin composition thus obtained was cut into multiple test pieces each having a width of 5 mm, a length of 50 mm, and a thickness of 0.2 mm

Each of these test pieces thus obtained was subjected to measurement in a bending mode using a viscoelasticity spectrometer (model number DMA7100 manufactured by Hitachi High-Tech Corporation) and its glass transition temperature and elastic modulus when heated were calculated by the DMA method. The glass transition temperatures (° C.) of the cured products thus obtained are shown in Table 1.

2.2. Coefficient of Linear Thermal Expansion (α1)

In the first to ninth examples, the side-filling resin composition was photo-cured under the same light irradiation condition as the one described for the item 2.1. to obtain a cured product of the side-filling resin composition. The cured product of the side-filling resin composition thus obtained was cut into multiple test pieces, each having a width of 3 mm, a length of 15 mm, and a thickness of 3 mm. Meanwhile, in the first comparative example, the side-filling resin composition was thermally cured under the same heating condition as the one described for the item 2.1 to obtain a cured product of the side-filling resin composition. The cured product of the side-filling resin composition thus obtained was cut into multiple test pieces each having a width of 3 mm, a length of 15 mm, and a thickness of 3 mm

Each of these test pieces was heated by a thermal analysis instrument (model number TMA7100 manufactured by Hitachi High-Tech Corporation) under the condition including a temperature increase rate of 5° C./min and a measuring temperature of 30 to 260° C., thereby calculating the coefficient of linear thermal expansion by the TMA method. The coefficient of linear thermal expansion (ppm/° C.) of the cured product thus obtained is shown in Table 1.

2.3. Repairability

On a glass epoxy substrate that had been subjected to solder resist treatment (base member: FR4 having a thickness of 0.6 mm and manufactured by Panasonic Corporation, and resist: PSR4000 manufactured by Taiyo Ink Mfg. Co., Ltd.), 10 mg of the side-filling resin composition formed as described in the item 1. was applied and cured, thereby forming a test piece including a cured product of the side-filling resin composition on the substrate. In the first to ninth examples, the curing condition was the same as the light irradiation condition described for the item 2.1. On the other hand, in the first to third comparative examples, the curing condition was the same as the heating condition described for the item 2.1.

Each of these test pieces was placed on a hotplate and heated for 10 minutes such that the substrate had a surface temperature of 200° C. After that, the operation of peeling the cured product off the substrate was performed using a bamboo skewer. Then, the conditions of the cured product and the substrate were inspected with the naked eye, thereby evaluating each test piece as one of the following three grades. The results are also shown in Table 1:
Grade A: if the cured product could be peeled off the substrate with no residues of the cured product left on the substrate;
Grade B: if the cured product could be peeled off the substrate but some residues of the cured product were left on the substrate; or
Grade C: if the cured product could not be peeled off the substrate and left on the substrate.

2.4. Temperature Cycle (TC) Characteristics

A test element group (TEG) was formed by mounting an IC chip for mounting (WLP TEG<BGA with a pitch of 0.3 mm>, 6 mm, manufactured by WALTS Co., Ltd.) on an FR-4 circuit board (WALTS KIT WLP300P manufactured by WALTS Co., Ltd.) having a daisy chain electrode. The side-filling resin composition that had been formed as described in the item 1 was applied to have the planar shape shown in FIG. 2B and a width of 0.8 mm and a height of 0.4 mm between the board and the peripheral edge portion of the surface, facing the board, of the IC chip in the TEG. The contact portion between the side-filling resin composition and the IC chip had a length of 2.5 mm. A test piece including a cured product of the side-filling resin composition was formed on the TEG by curing the side-filling resin composition applied. The curing condition was the same as the light irradiation condition as described in the item 2.1 as for the first to ninth examples and was the same as the heating condition as described in the item 2.1 as for the first to third comparative examples.

Each test piece thus formed was given a temperature variation in a gas phase using a thermal shock tester (model number TSE-12-A manufactured by ESPEC Corporation) to be exposed, in each cycle, to a temperature of ˜40° C. for 30 minutes and a temperature of 125° C. for 30 minutes. This thermal shock test was performed in 2000 cycles in total. The operation of the test piece was checked by measuring the resistance value of the test piece every 100 cycles. A test piece, of which the resistance varied by 10% or more since the beginning of the test, was determined to be malfunctioning and evaluated as one of the following three grades. The results are also shown in Table 1:
Grade A: if the test piece did not malfunction even after having gone through more than 2000 cycles;
Grade B: if the test piece started to malfunction when the test piece went through the temperature cycles, of which the number was equal to or larger than 500 and equal to or less than 2000 cycles; or
Grade C: if the test piece started to malfunction when the test piece went through less than 500 cycles.

2.5. Thixotropic Property Test

The side-filling resin composition that had been formed as described in the item 1 was loaded into a circular cylindrical container to have its viscosity value measured using a Type B viscometer (model number TVB10 manufactured by Told Sangyo Co., Ltd.) under the condition including a rotor No. 7, the number of revolutions of 10 rpm, and a measuring time of 60 seconds. A thixo index was calculated by dividing the viscosity value at 1 rpm by the viscosity value at 10 rpm.

2.6. Adhesion Strength (Shear Strength) Test

A glass epoxy substrate (base member: FR4 having a thickness of 0.6 mm and manufactured by Panasonic Corporation) was treated with a resist (PSR4000 manufactured by Taiyo Ink Mfg. Co., Ltd.), thereby forming a solder resist layer. In this manner, a substrate, in which the glass epoxy substrate was coated with the solder resist layer, was formed. Next, a silicon plate, having a hole with a diameter of 3 mm and a thickness of 1 mm, was laid on top of the substrate thus formed, the hole was filled with the side-filling resin composition described in the item 1, the side-filling resin composition was cured, and then the silicon plate was removed, thereby obtaining a test piece for measuring the shear strength. The side-filling resin composition was cured with an LED UV irradiator (model number Aicure UD40 manufactured by Panasonic Industrial Device SUNX Co., Ltd.) by irradiating the side-filling resin composition at a wavelength of 365 nm and an intensity (quantity) of 1000 mW/cm² for 4 seconds.

The test piece thus formed had its shear strength value measured by using a bond tester (Nordson DAGE 4000 Optima) under the condition including a load cell of S200KG, a test height of 50 μm, and a test speed of 500 μm/s.

TABLE 1

| | | | Examples | | | | | | | | | Comparative examples | | |
|---|---|---|---|---|---|---|---|---|---|---|---|---|---|---|
| | | | 1 | 2 | 3 | 4 | 5 | 6 | 7 | 8 | 9 | 1 | 2 | 3 |
| Composition | Photopolymerizable | Epoxy resin 1 | 9.0 | 12.0 | 7.0 | 9.0 | 8.5 | 8.0 | — | — | 21.0 | 7.5 | 18.0 | 15.0 |
| (parts by | Component | Epoxy resin 2 | 9.0 | 12.0 | 7.0 | 9.0 | 8.5 | 5.0 | 15.0 | 10.0 | 21.0 | 7.0 | 18.0 | 15.0 |
| weight) | | Epoxy resin 3 | — | — | — | — | — | — | 10.0 | 15.0 | | — | — | — |
| | | Oxetane resin | 10.0 | 14.0 | 9.0 | 10.8 | 10.0 | 15.0 | 3.0 | 3.0 | 25.0 | — | — | — |
| | Polymerization | Photopolymerization | 1.0 | 1.0 | 1.0 | 0.2 | — | 1.0 | 1.0 | 1.0 | 2.0 | — | — | — |
| | | initiator 1 | | | | | | | | | | | | |
| | Initiator | Photopolymerization | — | — | — | — | 1.5 | — | — | — | — | — | — | — |
| | | initiator 2 | | | | | | | | | | | | |

| | | | | | | | | | | | | | |
|---|---|---|---|---|---|---|---|---|---|---|---|---|---|
| | Photosensitizer | — | — | — | — | — | | — | — | — | — | — | — |
| | Thermosetting agent 1 | — | — | — | — | — | — | — | — | — | 13.5 | — | — |
| | Thermosetting agent 2 | — | — | — | — | — | — | — | — | — | 1.0 | 2.0 | 2.0 |
| | Inorganic filler | 70.0 | 60.0 | 75.0 | 70.0 | 70.0 | 70.0 | 70.0 | 70.0 | 30.0 | 70.0 | 60.0 | 60.0 |
| | Thixotropic property imparting agent | 1.0 | 1.0 | 1.0 | 1.0 | 1.0 | 1.0 | 1.0 | 1.0 | 1.0 | 1.0 | 2.0 | 2.0 |
| | Flexibility imparting agent | — | — | — | — | — | — | — | — | — | — | — | 6.0 |
| | Total | 100.0 | 100.0 | 100.0 | 100.0 | 100.0 | 100.0 | 100.0 | 100.0 | 100.0 | 100.0 | 100.0 | 100.0 |
| Evaluation | Glass transition temperature (Tg) [° C.] | 140 | 140 | 140 | 140 | 135 | 150 | 130 | 120 | 150 | 160 | 160 | 120 |
| | Coefficient of linear thermal | 32 | 38 | 30 | 30 | 32 | 32 | 34 | 33 | 50 | 22 | 34 | 35 |
| | expansion (αl) [ppm/° C.] | | | | | | | | | | | | |
| | Thixotropic property (Thixo Index TI) | 5.2 | 4.0 | 5.8 | 5.0 | 5.2 | 4.8 | 4.6 | 5.1 | 2.2 | 4.5 | 3.5 | 3.3 |
| | Shear strength [MPa] at 125° C. | 5.0 | 5,8 | 4.5 | 3.6 | 4.2 | 6.2 | 2.5 | 3.1 | 6.8 | 12.6 | 10.2 | 2.8 |
| | Shear strength [MPa] at 200° C. | 0.1 | 0.1 | 0.1 | 0.1 | 0.1 | 0.5 | 0.1 | 0.1 | 0.1 | 4.6 | 3.9 | 0.9 |
| | Repairability | A | A | A | A | A | B | A | A | A | C | C | B |
| | Temperature cycle (TC) characteristic | A | A | A | A | A | A | B | B | B | A | A | C |

### REFERENCE SIGNS LIST

1 Semiconductor Device
2 Base Member
3 Mounted Component
4 Side-Filling Member

1. A side-filling resin composition for use to form a side-filling member to be interposed between a base member and a peripheral edge portion of a surface, facing the base member, of a mounted component that is surface-mounted on the base member, the side-filling resin composition having photocurability.

2. The side-filling resin composition of claim 1, wherein
a cured product of the side-filling resin composition has a glass transition temperature equal to or higher than 130° C., and the cured product has a coefficient of linear thermal expansion less than 40 ppm/° C. at a temperature equal to or lower than the glass transition temperature.

3. The side-filling resin composition of claim 1, wherein
in a cured product formed by curing the side-filling resin composition on a glass epoxy substrate that has been subjected to solder resist treatment, a shear strength, measured with a bond tester, of the cured product with respect to the substrate is equal to or greater than 3 MPa when the cured product has a temperature of 125° C. and is equal to or less than 0.3 MPa when the cured product has a temperature of 200° C.

4. The side-filling resin composition of claim 1, containing a photo-cationic polymerizable compound (A1) and a cationic photo-polymerization initiator (B1).

5. The side-filling resin composition of claim 1, containing an inorganic filler (C).

6. A semiconductor device comprising: a base member; a mounted component that has been surface-mounted on the base member; and a side-filling member interposed between the base member and a peripheral edge portion of a surface, facing the base member, of the mounted component,
the side-filling member being made of a cured product of the side-filling resin composition of claim 1.

7. A method for removing a side-filling member, the method including removing the side-filling member of the semiconductor device of claim 6 from between a peripheral edge portion of the mounted component and the base member while heating the side-filling member to a temperature equal to or higher than 200° C.
